(19) United States
(12) Patent Application Publication
(10) Pub. No.: US 2010/0289554 A1
(43) Pub. Date: Nov. 18, 2010

(54) ELECTRONIC DEVICE AND METHOD FOR PLAYING DIGITAL CONTENT

(75) Inventor: CHIEN-CHUN FU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/498,740

(22) Filed: Jul. 7, 2009

(30) Foreign Application Priority Data
May 18, 2009 (CN) 200910302398.3

(51) Int. Cl. H03K 17/945

(52) U.S. Cl. 327/517

(57) ABSTRACT

An electronic device includes a detecting module, a signal processing module connected to the detecting module, a controlling module connected to the signal processing module and a display connected to the controlling module. The detecting module outputs a first detect signal to the signal processing module when a human body is present in front of the display. The signal processing module transforms the first detect signal into a first control signal and outputs the first control signal to the controlling module. The controlling module causes digital content to be played on the display.

### BACKGROUND

1. Technical Field

The disclosure generally relates to display assemblies and methods for playing digital content, especially to an electronic device and a method for playing digital content of an electronic device.

2. Description of Related Art

Some consumer electronics, such as a television, a digital phone frame (DPF), a MP4 player and etc may have displays for displaying digital content. When using these consumer electronics, the digital content may be uninterruptedly played until the power is turned off. Sometime the user may leave away and forget to turn off the consumer electronics, the consumer electronics may continue to play, and it is a waste of energy.

### BRIEF DESCRIPTION OF THE DRAWINGS

FIG. 1 is a schematic view of an electronic device.

FIG. 2 is a block view of the electronic device of FIG. 1.

FIG. 3 is a flowchart of a method for playing digital content in the electronic device.

### DETAILED DESCRIPTION

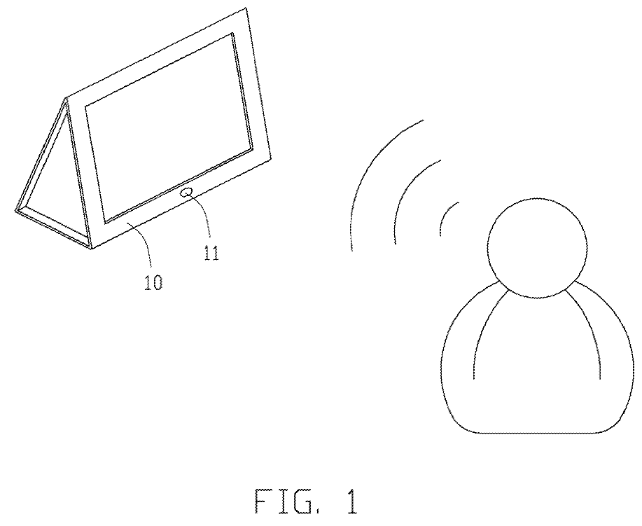

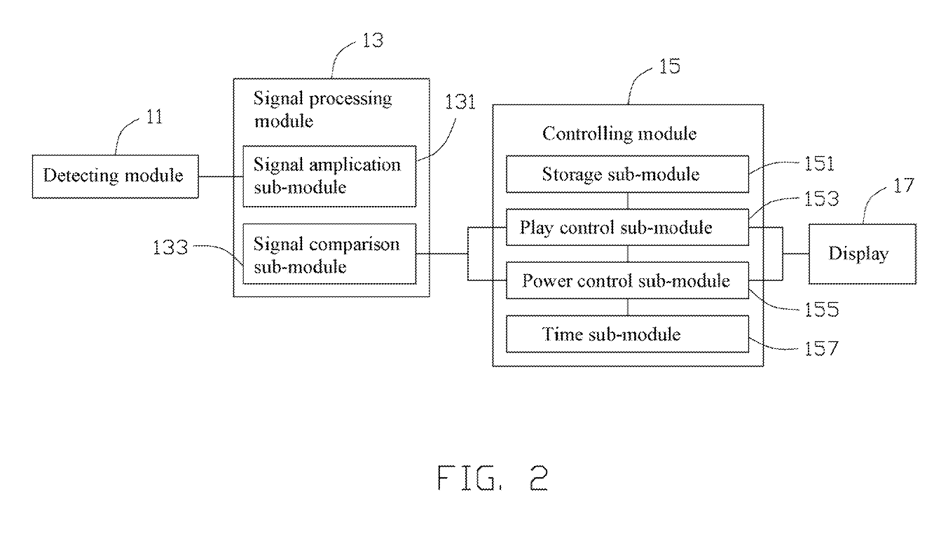

Referring to FIG. 1 and FIG. 2, an electronic device 10 includes a detecting module 11, a signal processing module 13, a controlling module 15 and a display 17. The detecting module 11 is one of an infrared (IR) sensor, an ultrasonic sensor, and other similar sensors for detecting the presence of a human body. The IR sensor is configured to detect the presence of a human body from a body temperature.

The signal processing module 13 includes a signal amplification sub-module 131 and a signal comparison sub-module 133. The signal amplification sub-module 131 is configured for amplifying a detect signal and outputting an amplified detect signal to the signal comparison sub-module 133. The signal comparison sub-module 133 is configured for comparing the amplified detect signal with a standard signal to generate a control signal.

The controlling module 15 includes a storage sub-module 151, a play control sub-module 153, a power control sub-module 155, and a time sub-module 157. The storage sub-module 151 is configured for storing digital content. The play control sub-module 153 is configured to selectively start/continue the digital content. The power control sub-module 155 is configured for powering on or powering off the display 17. The time sub-module is configured for setting a predetermined delay time before powering off the display 17. The display 17 is configured for displaying the digital content.

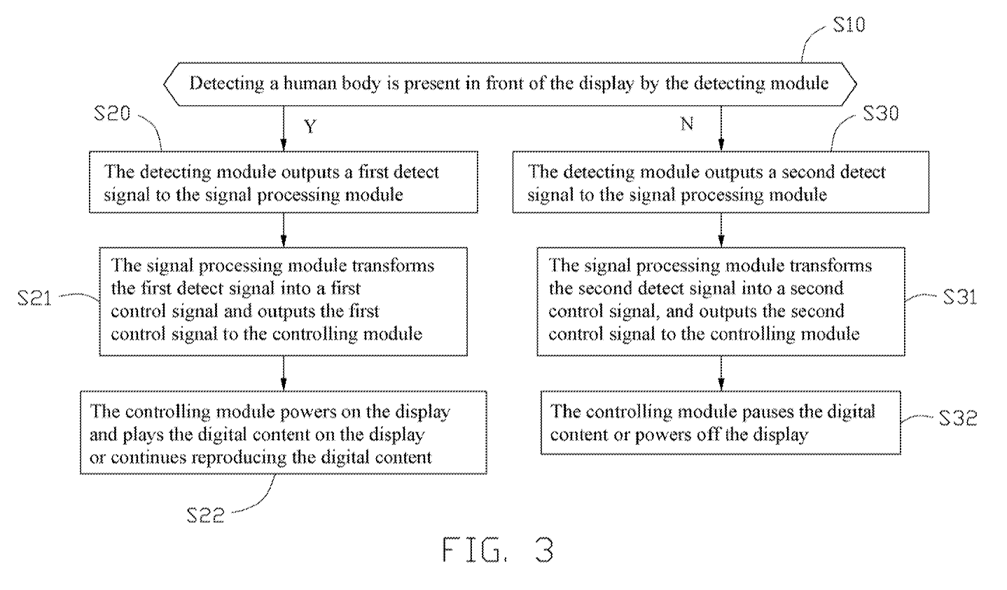

Referring to FIG. 3, a method for playing digital content in the electronic device 10 includes the following steps:

S10: detecting whether a human body is present in front of the display 17 by the detecting module 11, if yes go to S20, if no go to S30.

S20: the detecting module 17 outputs a first detect signal to the signal processing module 13.

S21: the signal processing module 13 transforms the first detect signal into a first control signal, and outputs the first control signal to the controlling module 15.

S22: the controlling module 15 powers on the display 17 and plays the digital content on the display 17 if the display 17 is powered off, or continues reproducing the digital content if the digital is paused.

S30: the detecting module 11 outputs a second detect signal to the signal processing module 13.

S31: the signal processing module 13 transforms the second detect signal into a second control signal, and outputs the second control signal to the controlling module 15.

S32: the controlling module 32 pause the digital content if the display is playing, or powers off the display 17 if the digital content is paused for a predetermined delay time.

In this embodiment, the first detect signal is a high level signal or a low level signal, and the second detect signal is the opposite of the first detect signal. The electronic device 10 is an embedded electronic device. The signal processing module 13 and the controlling module 17 are embedded system components.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the invention to the full extent indicated by the broad general meaning of the terms in which the appended claims are expressed.

It is also to be understood that the above description and the claims drawn to a method may include some indication in reference to certain steps. However, the indication used is only to be viewed for identification purposes and not as a suggestion as to an order for the steps.

What is claimed is:

1. An electronic device, comprising:
a detecting module;
a signal processing module connected to the detecting module;
a controlling module connected to the signal processing module; and
a display connected to the controlling module;
wherein the detecting module outputs a first detect signal to the signal processing module when a human body is present in front of the display, the signal processing module transforms the first detect signal into a first control signal and outputs the first control signal to the controlling module, the controlling module causes the digital content to be played on the display.

2. The electronic device of the claim 1, wherein the signal processing module further comprises a signal amplification sub-module and a signal comparison sub-module, the signal amplification sub-module is configured for amplifying the first detect signal and outputting the amplified first detect signal to the signal comparison sub-module, and the signal comparison sub-module is configured for comparing the amplified first detect signal with a standard signal.

3. The electronic device of the claim 1, wherein when the detecting module outputs a second detect signal to the signal processing module when no human body is present, the signal processing module transforms the second detect signal into a second control signal and outputs the second control signal to the controlling module, and the controlling module causes the digital content on the display to be paused on the condition that the display is playing.

4. The electronic device of the claim 3, wherein the controlling module is capable of causing the digital content to be played on the display when the first control signal is received by the controlling module and the digital content is paused.

5. The electronic device of the claim 3, wherein the controlling module is capable of powering off the display on the condition that the digital content is paused for a predetermined delay time; and the controlling module comprises a time sub-module for setting the predetermined delay time.

6. The electronic device of the claim 3, wherein the first detect signal and the second detect signal are selected from the group consisting of a high level signal and a low level signal; and the second detect signal is different than the first detect signal.

7. The electronic device of the claim 1, wherein the controlling module comprises a storage sub-module for storing the digital content.

8. The electronic device of the claim 1, wherein the detecting module is an infrared (IR) sensor, and the IR sensor is configured to detect the presence of the human body from a body temperature.

9. The electronic device of the claim 1, wherein the signal processing module and the controlling module are embedded system components.

10. A method for playing digital content in an electronic device, comprising:
detecting the presence of a human body in front of a display by a detecting module;
the detecting module outputting a first detect signal to a signal processing module;
the signal processing module transforming the first detect signal into a first control signal, and outputting the first control signal to a controlling module; and
the controlling module causing the digital content to be played on the display.

11. The method of claim 10 further comprising: the signal processing module amplifying the first detect signal and comparing the amplified first detect signal with a standard signal.

12. The method of claim 10 further comprising:
detecting the presence of human body in front of the display by the detecting module;
the detecting module outputting a second detect signal to the signal processing module;
the signal processing module transforming the second detect signal into a second control signal, and outputting the second control signal to the controlling module; and
the controlling module causing the digital content to be paused on the condition that the display is playing.

13. The method of claim 12 further comprising: the controlling module causing the digital content to be played on the display when the first control signal is received by the controlling module and the digital content is paused.

14. The method of claim 12 further comprising: the controlling module powering off the display on the condition that the digital content is paused for a predetermined delay time.

15. The method of claim 12, wherein the first detect signal and the second detect signal are selected from the group consisting of a high level signal and a low level signal; and the second detect signal is different than the first detect signal.

16. The method of claim 10, wherein the controlling module comprises a storage sub-module for storing the digital content.

17. The method of claim 10, wherein the detecting module is an infrared (IR) sensor, and the IR sensor is configured to detect the presence of the human body from a body temperature.

18. The method of claim 10, wherein the signal processing module and the controlling module are components in an embedded electronic device.
